(19) United States
(12) Patent Application Publication
(10) Pub. No.: US 2015/0361555 A1
(43) Pub. Date: Dec. 17, 2015

(54) CVD EPITAXIAL REACTOR CHAMBER WITH RESISTIVE HEATING, THREE CHANNEL SUBSTRATE CARRIER AND GAS PREHEAT STRUCTURE

(71) Applicant: Crystal Solar Inc., Santa Clara, CA (US)

(72) Inventors: Visweswaren Sivaramakrishnan, Cupertino, CA (US); Quoc Vinh Truong, San Leandro, CA (US); Timothy N. Kleiner, Los Gatos, CA (US); Tirunelveli S. Ravi, Saratoga, CA (US)

(21) Appl. No.: 14/738,777

(22) Filed: Jun. 12, 2015

Related U.S. Application Data
(60) Provisional application No. 62/011,549, filed on Jun. 12, 2014.

(51) Int. Cl. C23C 16/46; C23C 16/455; C23C 16/458

(52) U.S. Cl. CPC C23C 16/46; C23C 16/458; C23C 16/455

(57) ABSTRACT

A CVD reactor for depositing material on substrates may comprise: a vacuum chamber; at least two substrate carriers arranged in parallel in a row within the vacuum chamber, each of the at least two substrate carriers comprising mounting positions for a plurality of substrates, the mounting positions being on the walls of channels configured for flowing process gases, the channels being in parallel planes within all of the at least two substrate carriers; a planar electrically resistive heater between every two adjacent substrate carriers in the row; and planar heaters at both ends of the row. Furthermore, CVD reactor chambers with three channel substrate carriers and/or gas preheat structure are described herein.

### CROSS-REFERENCE TO RELATED APPLICATIONS

This application claims the benefit of U.S. Provisional Application No. 62/011,549 filed Jun. 12, 2014, incorporated by reference in its entirety herein.

### FIELD OF THE INVENTION

The present invention relates generally to CVD (chemical vapor deposition) epitaxial reactors, including, although not limited to, CVD reactor chambers with resistive heating, three channel substrate carriers and/or gas preheat structures.

### BACKGROUND

There is a need for tools and methods for efficient and low cost chemical vapor deposition (CVD) of epitaxial single crystal silicon.

### SUMMARY OF THE INVENTION

According to some embodiments, a CVD reactor for depositing material on substrates may comprise: a vacuum chamber; at least two substrate carriers arranged in parallel in a row within the vacuum chamber, each of the at least two substrate carriers comprising mounting positions for a plurality of substrates, the mounting positions being on the walls of channels configured for flowing process gases, the channels being in parallel planes within all of the at least two substrate carriers; a planar electrically resistive heater between every two adjacent substrate carriers in the row; and planar heaters at both ends of the row. Furthermore, the planar heaters may be lamp heaters and the lamp heaters may be mounted externally on the vacuum chamber. Furthermore, the planar heaters may be planar electrically resistive heaters and the planar heaters may be mounted within the vacuum chamber.

According to some embodiments, a substrate carrier for holding substrates in a CVD reactor may comprise: mounting positions for a plurality of substrates, the mounting positions being on the walls of three channels configured for flowing process gases, the channels being in parallel planes within the substrate carrier; and two gas preheat modules, a first of the two gas preheat modules being coupled to first ends of the three channels and a second of the two gas preheat modules being coupled to second ends of the three channels; wherein mounting positions on the walls of the center of the three channels are positioned further from the proximate of the two gas preheat modules than the mounting positions on the walls of the outer two of the three channels.

According to some embodiments, a CVD reactor for depositing material on substrates may comprise: a gas manifold; a substrate carrier mated to the gas manifold, the substrate carrier comprising a process gas preheat module, the process gas preheat module comprising an outer portion with a tortuous channel therein, an inner portion with a substantially straight channel therein, and a gas mixing chamber, wherein the tortuous channel connects an intake port of a first process gas to the mixing chamber and the substantially straight channel connects an intake port of a second process gas to the mixing chamber; and a heater external to the gas preheat module and adjacent to the outer portion.

According to some embodiments, a method of operating a CVD reactor may comprise: flowing a first process gas from a first intake port of a gas manifold through a tortuous channel in an outer portion of a process gas preheat module into a mixing chamber; while flowing the first process gas, flowing a second process gas from a second intake port of the gas manifold through a substantially straight channel in an inner portion of the process gas preheat module into the mixing chamber; while flowing the first process gas and the second process gas, heating the gas preheat module with a heater external to the gas preheat module and adjacent to the outer portion; flowing a mixture of the first process gas and the second process gas from the mixing chamber through channels lined with a plurality of substrates and depositing material on the exposed surfaces of the plurality of substrates.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a perspective view of representation of an epitaxial reactor, according to embodiments of the present invention;

FIG. 2A is a first cut-away perspective view of an epitaxial reactor with a resistive heater, according to some embodiments of the present invention;

FIG. 2B is a second cut-away perspective view of an epitaxial reactor with a resistive heater, according to some embodiments of the present invention;

FIG. 2C is a view in to a vertically cut epitaxial chamber with a resistive heater, according to some embodiments of the present invention;

FIG. 3 is shows 5 resistive strips and support structures as configured as a heater for an epitaxial reactor, according to some embodiments of the present invention;

FIG. 4A is a first cut-away perspective view of an epitaxial reactor with multiple electrically resistive heaters, according to some embodiments of the present invention;

FIG. 4B is a second cut-away perspective view of an epitaxial reactor with multiple electrically resistive heaters, according to some embodiments of the present invention;

FIG. 5A is a perspective view of a three channel substrate carrier, according to some embodiments of the present invention;

FIG. 5B is a view in to the vertically cut three channel substrate carrier of FIG. 5A, according to some embodiments of the present invention;

FIG. 5C is a perspective exploded view of select parts of the three channel substrate carrier of FIG. 5A, according to some embodiments of the present invention;

FIG. 6 is a cross-sectional representation of the upper portion of a substrate carrier including a gas manifold, a preheat module and a three channel substrate holding module, according to some embodiments of the present invention; and

FIG. 7 is a cross-sectional representation of a gas manifold and a preheat module, according to some embodiments of the present invention.

### DETAILED DESCRIPTION

Embodiments of the present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

The present disclosure describes modifications to the general CVD epitaxial reactor designs described in Pat. Appl. Publ. Nos. US 2010/0215872, US 2010/0263587 and US 2013/0032084, all incorporated by reference in their entirety herein. It is desired to increase the number of substrates that may be simultaneously processed in a CVD epitaxial reactor—for example, for epitaxial silicon deposition on single crystal silicon substrates.

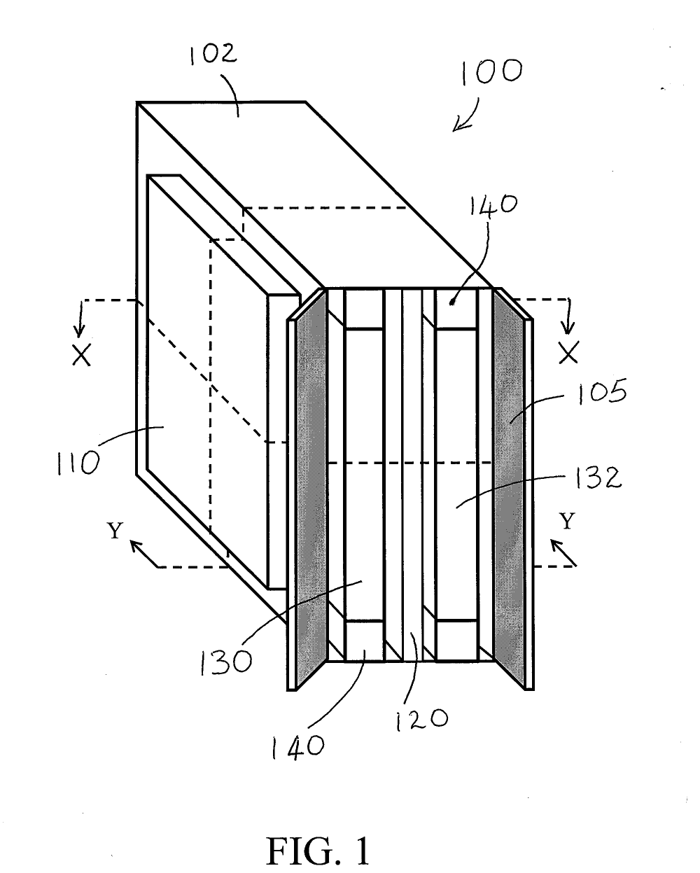

FIG. 1 shows a perspective view of a representation of a CVD epitaxial reactor 100 according to some embodiments of the present invention. The reactor 100 comprises a reactor vacuum chamber 102 with doors 105, external heating units 110 attached to the outside of the chamber 102 on both sides of the reactor, an internal resistive heater 120, two substrate carriers 130 and 132, the carriers being removable from the chamber for loading and unloading, and gas manifolds 140 positioned at top and bottom of each of the substrate carriers for delivering and exhausting gases.

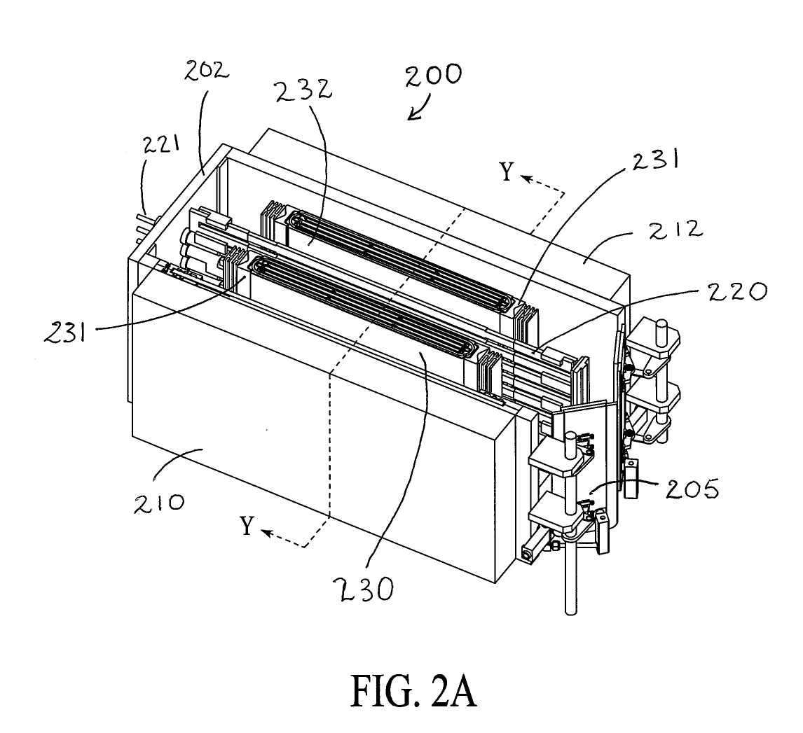

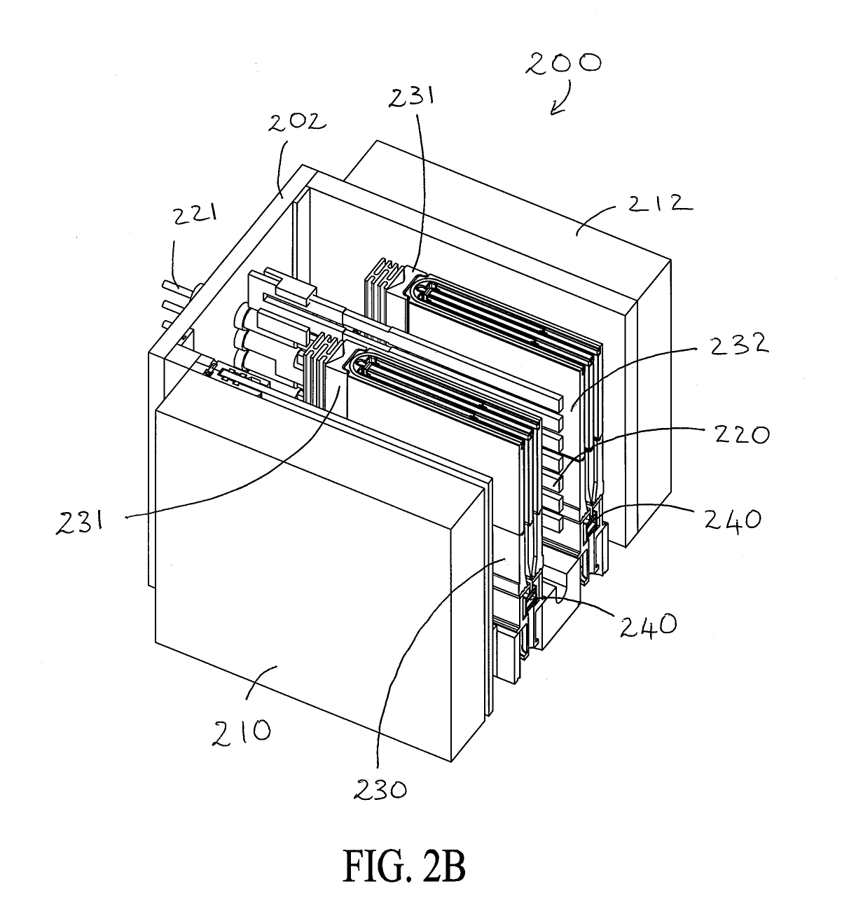

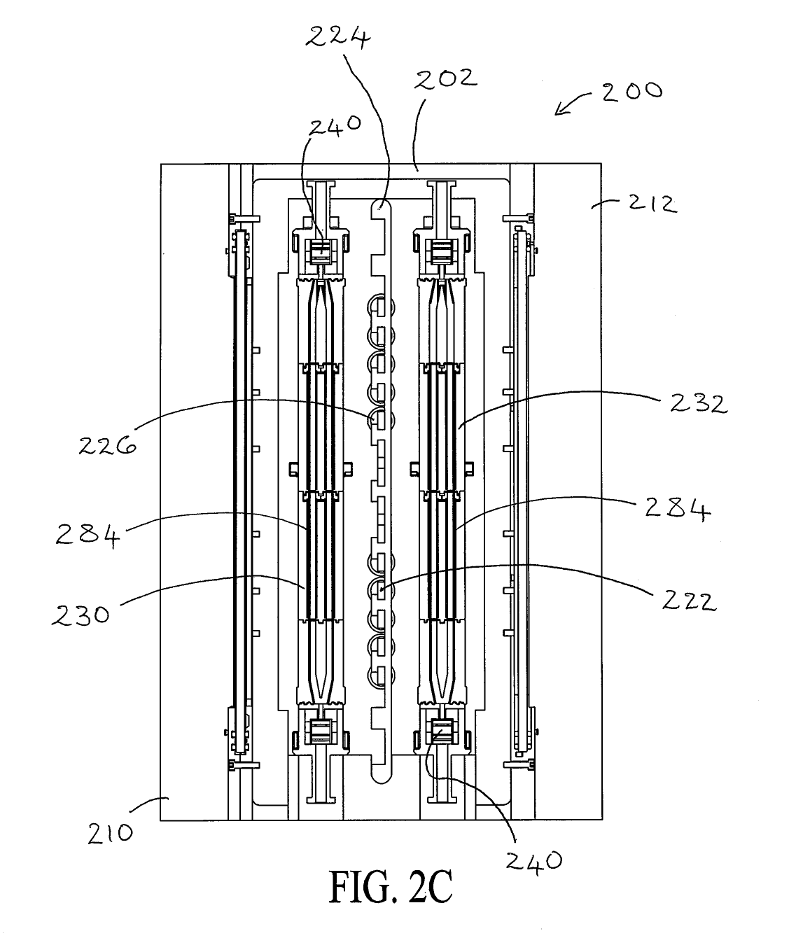

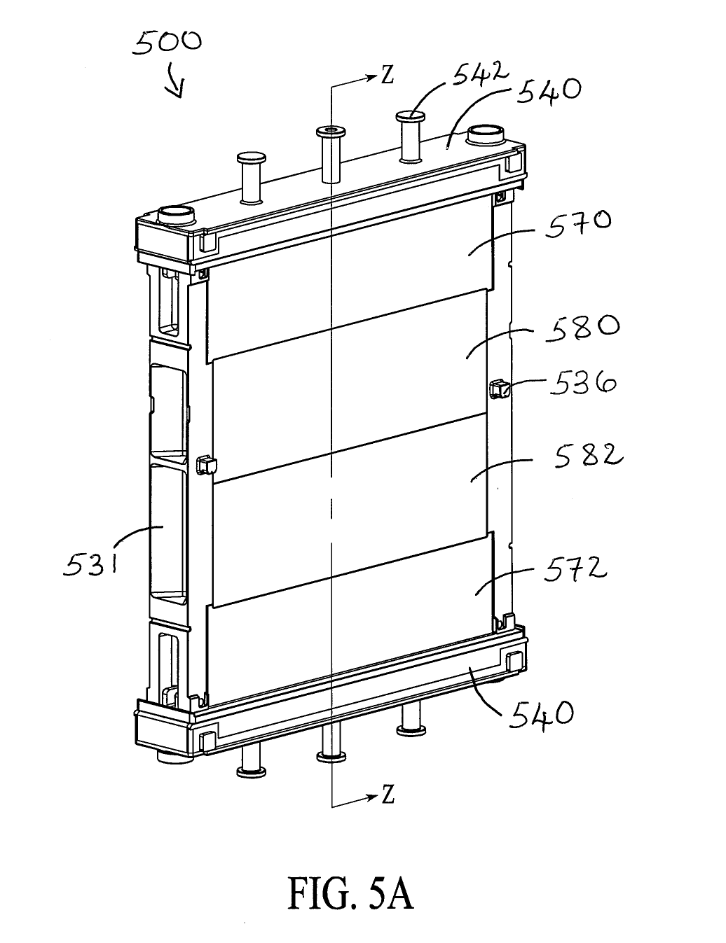

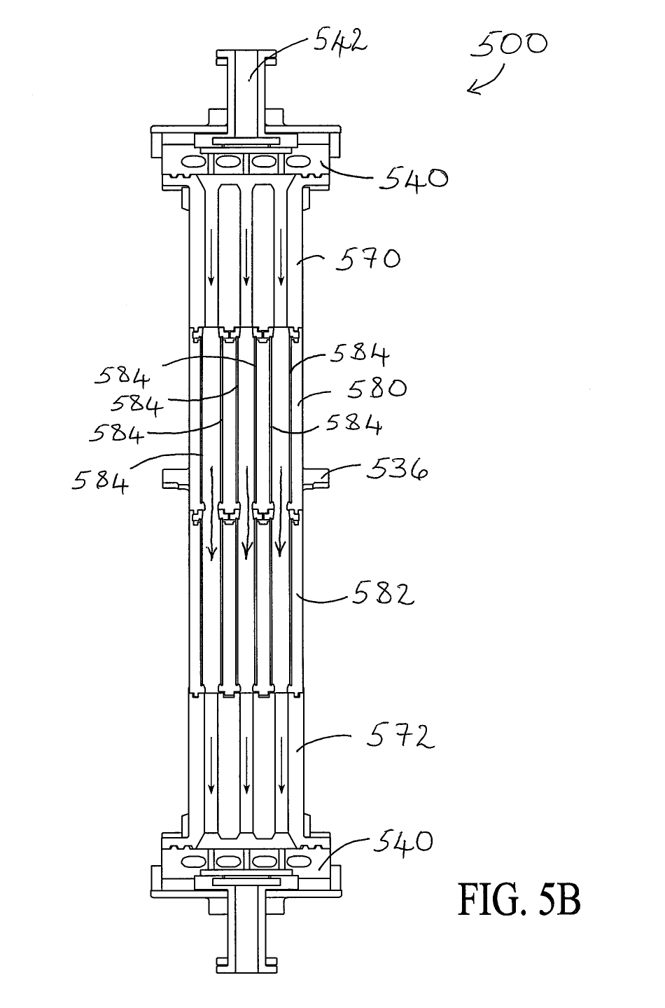

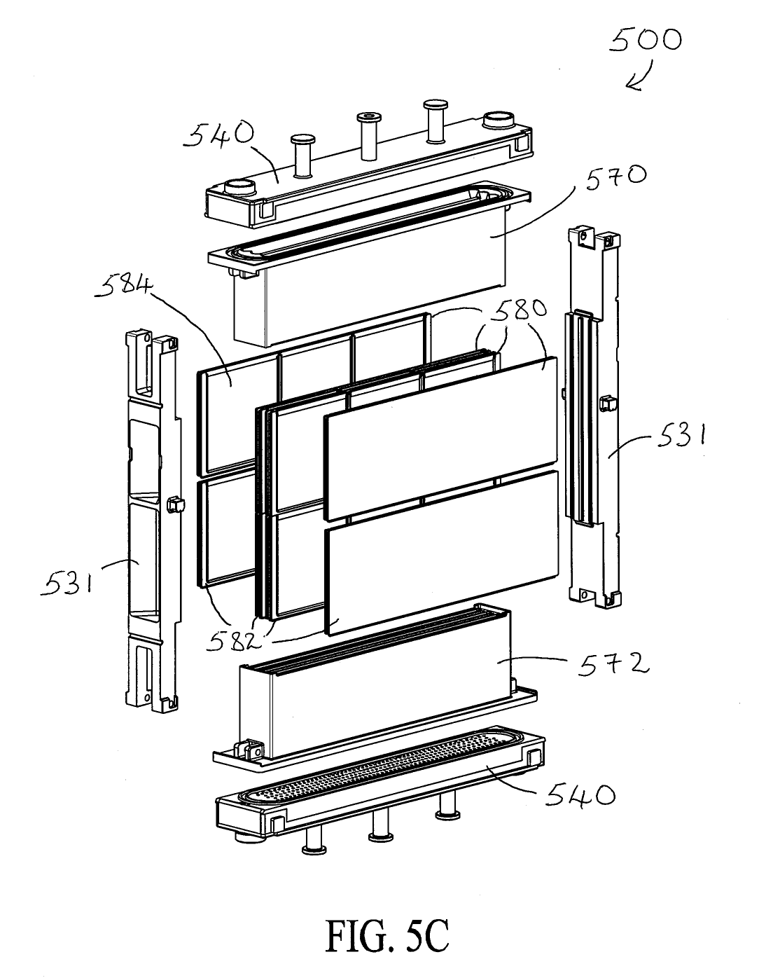

FIGS. 2A-2C show different views of a CVD epitaxial reactor 200 according to embodiments of the present invention. FIGS. 2A & 2B are cutaway views—FIG. 2A with reactor chamber top cut away (along plane defined by section X-X) and FIG. 2B with both reactor chamber top cut away (along plane defined by section X-X) and reactor chamber front cutaway (along plane defined by section Y-Y). FIG. 2C is a view in to the reactor chamber, where the reactor chamber front has been cut away (along plane defined by section Y-Y). The epitaxial reactor 200 is configured for simultaneous processing of substrates in two substrate carriers 230 & 232 and comprises, for heating the two substrate carriers, both lamp array heaters 210 & 212 and an electrically resistive heater 220, the electrically resistive heater having an array of electrically resistive strips. The lamp heaters are on the external walls of the reactor vacuum chamber 202 and the electrically resistive heater is between the two substrate carriers. Note that the electrically resistive heater may be in the vacuum environment of the reactor and there does not need to be a window between the electrically resistive heater and the substrate carriers. (This is in contrast to the lamp heaters which are generally isolated from the vacuum environment by a quartz window in the vacuum chamber wall in order to facilitate cooling of the lamps.) Electrical feedthroughs 221 mounted in the back vacuum chamber wall are used to supply current to the electrically resistive heating elements 222 in the electrically resistive heater 220. The electrically resistive heating elements 222 are supported by support structures 224. The vacuum chamber ends 226 of the electrical feedthroughs 221 are seen at the back of the vacuum chamber in FIG. 2C. Substrate carriers are inserted in to and removed from the reactor through vacuum chamber doors 205. The substrate carriers 230 & 232 are mated to gas manifolds 240 at top and bottom. The substrate carriers are shown loaded with substrates 284. The particular embodiment of substrate carrier shown in FIG. 2C is a two channel carrier, although three channel carriers may also be used. Further details of embodiments of substrate carriers are provided below with reference to FIGS. 5A-5C. Further details of epitaxial reactors, substrate carriers and lamp heaters that may be applicable to some embodiments of the present invention can be found in Pat. Appl. Publ. Nos. US 2010/0215872, US 2010/0263587 and US 2013/0032084, all incorporated by reference herein in their entirety.

Furthermore, the general configuration of FIGS. 2A-C may be extended to include 3 or more substrate carriers by adding more slots for substrate carriers within the vacuum chamber with an electrically resistive heater between each pair of adjacent substrate carriers, where the substrate carriers are all positioned in parallel in the same manner as shown in the present figures.

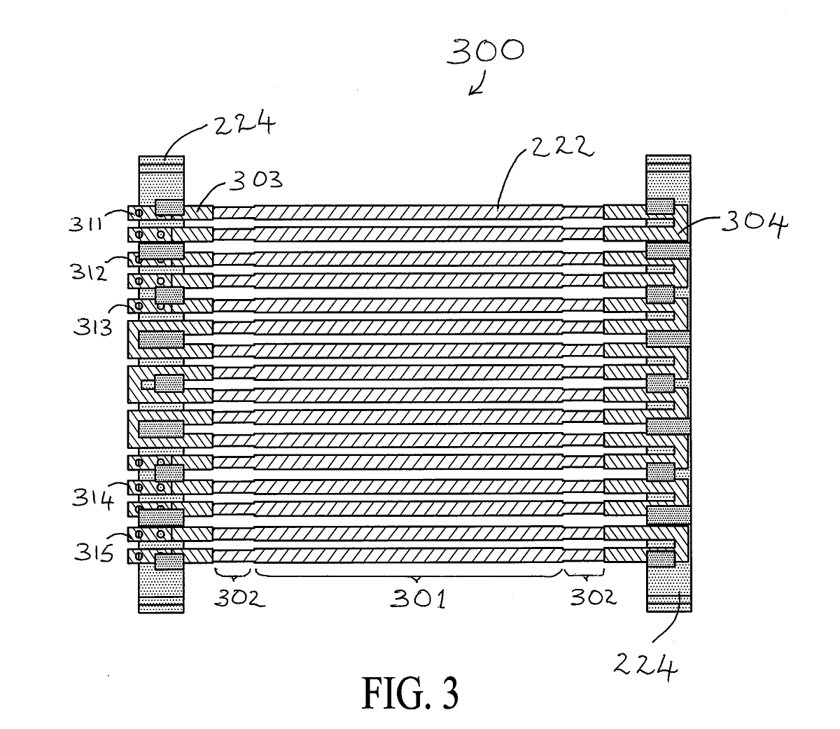

FIG. 3 shows an example of an electrically resistive heater structure 300 comprising 5 electrically resistive heating elements 311, 312, 313, 314 and 315 corresponding to 5 heating zones, where the heat generated from each element can be controlled separately by controlling the current passing through each element. The concept of different heating zones is discussed in more detail in Pat. Appl. Publ. Nos. US 2010/0215872, US 2010/0263587 and US 2013/0032084, all incorporated by reference herein in their entirety. As an example, the electrically resistive elements may be made of graphite CVD coated with SiC, available from Toyo Tanso USA, Inc. The elements 222 are shown in the example of FIG. 3 to be serpentine, for the convenience of having all of the electrical contacts 303 on one side, and also to allow for uniform heating over an entire zone. The elements are held in place by support structures 224 at either end; the elements have contact portions 303, 304 where the elements are attached to the support structures and where electrical contact is made. In certain embodiments, each element has first heat emissive portions 301 which are adjacent to the part of the substrate carrier where the substrates are held, and second heat emissive portions 302 which are hotter during operation due to the element having a smaller cross-sectional area in these portions than the element in the first heat emissive portions. (The portions of the element with smaller cross-sectional area will have a higher electrical resistance and thus run hotter when a current flows through the element.) These second heat emissive portions 302 are adjacent to substrate carrier end caps 231, 431 (see FIGS. 2A, 2B & 4B), and the extra heat is intended to provide heat to the end caps to ensure that the temperature across the entire width of the substrates and half plate assemblies in the substrate carrier is the same—avoiding a temperature drop at the edges of the substrates and half plate assemblies adjacent to the end caps.

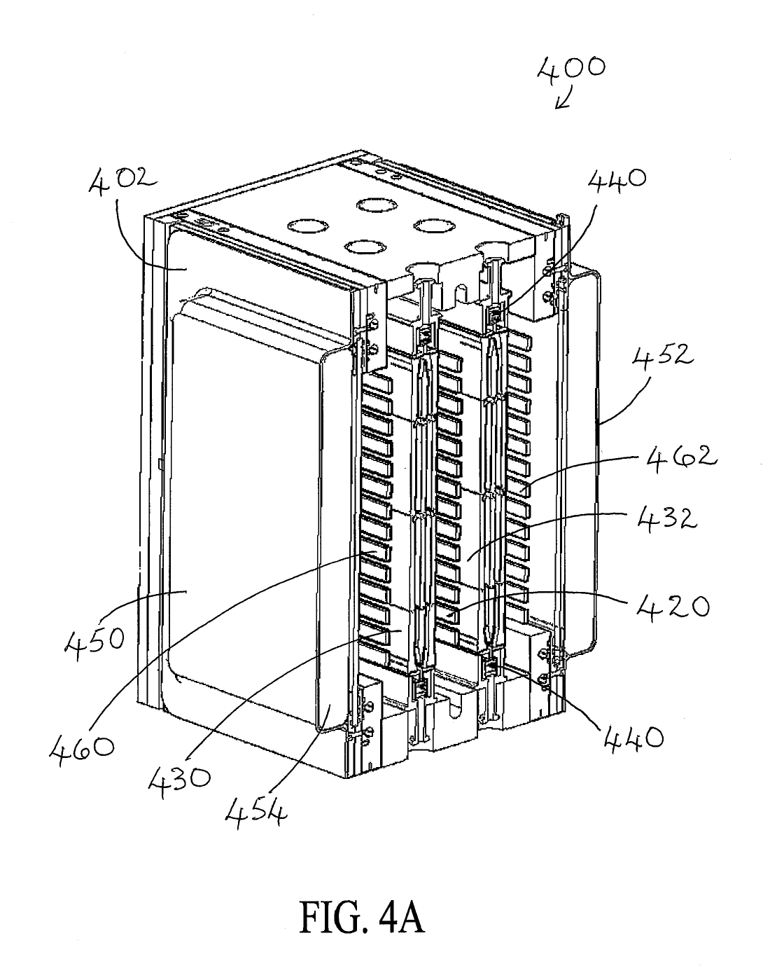

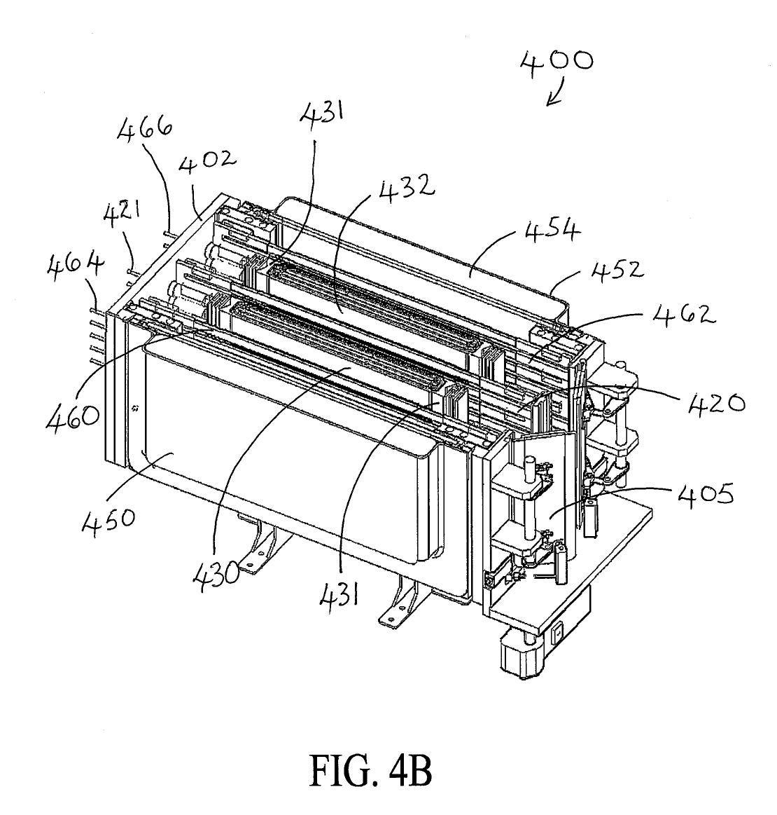

FIGS. 4A & 4B show cutaway perspective views of an epitaxial reactor 400 in which all of the heaters 420, 460 & 462 are arrays of electrically resistive elements—no lamp heaters are used in this embodiment. FIG. 4A is shown with reactor chamber front cutaway (along plane defined by section Y-Y in FIG. 1) and FIG. 4B is shown with the reactor chamber top cut away (along plane defined by section X-X in FIG. 1). In the example shown, there are two substrate carriers 430 & 432 and 3 electrically resistive heaters—two electrically resistive heaters 460 & 462 on the external walls of the reactor vacuum chamber 402 and the third electrically resistive heater 420 between the two substrate carriers. Electrical feedthroughs 421, 464 & 466, which are mounted in the back vacuum chamber wall, are used to supply current to the electrically resistive heaters 420, 460 & 462, respectively. Note the insulated panels 450 & 452 (for example, a sheet metal skin with insulation 454 within) on the outer walls of the reactor vacuum chamber adjacent to the electrically resistive heaters 460 & 462, respectively, to minimize heat loss from the reactor 400. The substrate carriers 430 & 432 are mated to gas manifolds 440 at top and bottom. Substrate carriers are inserted in to and removed from the reactor through vacuum chamber doors 405.

Furthermore, in order to simultaneously process large numbers of substrates in the epitaxial CVD reactors described herein, and described in Pat. Appl. Publ. Nos. US 2010/0215872, US 2010/0263587 and US 2013/0032084, all incorporated by reference in their entirety herein, in some embodiments a substrate carrier with three or more channels may be utilized. However, controlling the process gas temperature within the carrier becomes more challenging as the number of channels and thus the thickness of the substrate carrier increases, considering that the temperature is controlled by the lamp/electrically resistive heaters which are external to the substrate carriers as shown in FIGS. 2A-2C & 4A-4B. FIGS. 5A, 5B & 5C show views of a three channel substrate carrier 500, which in this particular example is configured to hold 36 166 mm substrates, although the substrate carrier may be configured to carry other numbers of substrates—for example 48 166 mm substrates. FIG. 5A is a perspective view of the substrate carrier 500, FIG. 5B is a view in to the vertically cut (along plane defined by Z-Z) three channel substrate carrier of FIG. 5A, and FIG. 5C is a perspective exploded view of select parts of the three channel substrate carrier of FIG. 5A. Substrate carrier 500 comprises: end caps 531, to which are attached handling features 536 for ease of transporting the substrate carrier using a robot or other fixture; gas manifolds 540 at top and bottom with gas inlets/outlets 542; gas preheat modules 570 & 572, mated to the gas manifolds at top and bottom, respectively; upper and lower half-plate assemblies 580 & 582, respectively, in which substrates 584 are mounted (mounting may be in slots, and/or by using clips, screws, or other mechanical fixtures), the half plate assemblies being mechanically coupled together and to the preheat modules at top and bottom. The preheat modules and half plate assemblies are configured as shown in the figures to form three channels which run from top to bottom from a first gas manifold through a first preheat module, the plate assemblies, a second preheat module and to the second gas manifold. The substrates 584 are shown held in place on the walls of the three channels such that the gas flows over the entire exposed surfaces of the substrates as the gas flows from one end of the substrate carrier to the other. The arrows in FIG. 5B illustrate one example of gas flow through the carrier—from top to bottom—although the gas flow may be reversed if needed to improve deposition uniformity. Having gas preheat modules 570 & 572 at top and bottom, respectively, allows for the process gases to be flowed in either direction through the carrier—from top to bottom or vice-versa during CVD deposition. The gas preheat modules, half plate assemblies and end caps are externally heated when placed in the reactor by a lamp and/or electrically resistive heaters, as described above. The length of the gas channels in the preheat module and the radiation incident on the preheat section can be configured/controlled to allow equal preheating of the gas in all three channels, such that the gas temperature in all three channels is the same on leaving the preheat section. Note also that extra heat may be applied to the end caps to compensate for heat loss from the sides of the substrate carrier, thus provide temperature uniformity across the width of the substrate carrier (perpendicular to the direction of process gas flow).

Furthermore, as shown above in FIG. 2C, for example, two channel substrate carriers may be used in the reactors of the present invention. (A detailed example of a two channel version of the substrate carrier may be found in Pat. Appl. Publ. No. US 2013/0032084.) Yet furthermore, in certain embodiments one channel substrate carriers may be used in the reactors of the present invention.

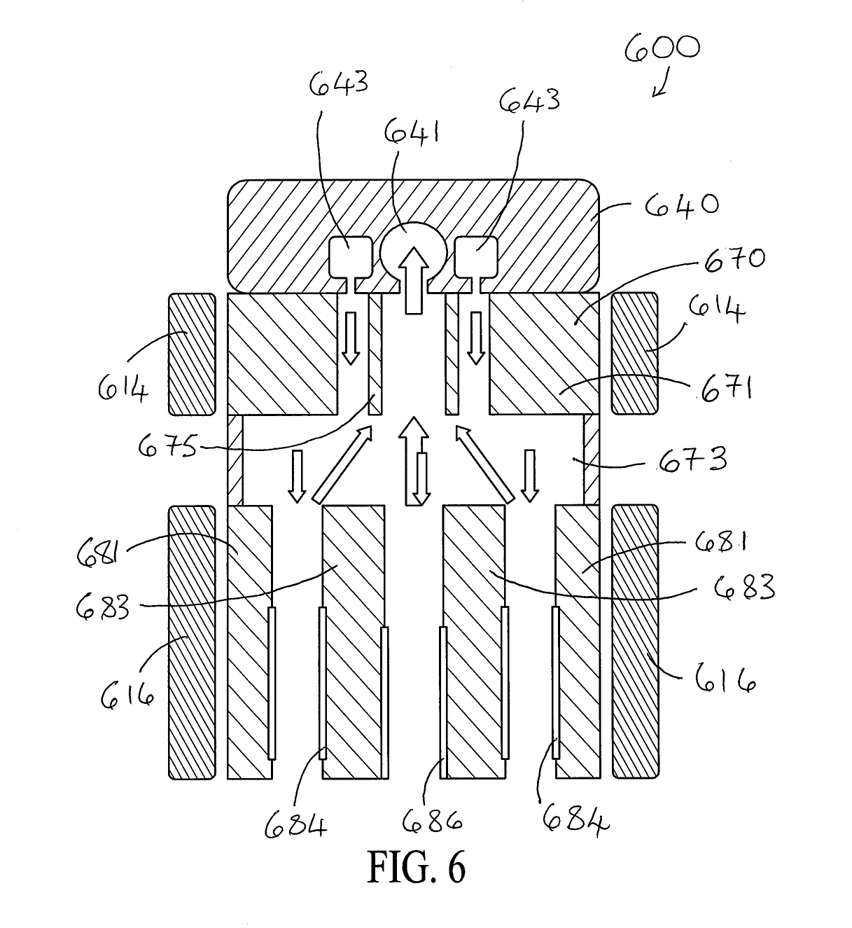

FIG. 6 shows a detail of a further embodiment of a three channel substrate carrier 600. FIG. 6 is a cross-sectional representation of the top half of a substrate carrier showing a gas manifold 640, a preheat module 670 with one or more gas channels (two process gas channels are shown in the example, although more or less may be used, where the channels are defined by the walls 671 and 675), a mixing region 673 that is configured to mix the process gas from the channels in the preheat module to ensure uniform gas temperature and flow on entering the three channel substrate holding module defined by external walls 681 and internal walls 683 onto which substrates 684 and 686 are mounted. Heating may be implemented using the lamp and/or electrically resistive heaters described above; furthermore, the heaters may be configured with heating zones corresponding to the different regions of the substrate carrier—for example, one zone for the preheat module and one or more zones for the substrate holding module (half plate assemblies). Heaters 614 are shown configured for heating the preheat module and heaters 616 are shown configured for heating the substrate holding module. Note that gas may be flowed in either direction through the substrate carrier—in the figure for the case of gas flowing from top to bottom of the carrier the inlet process gas flow is shown by the arrows pointing downwards and for the case of gas flowing from bottom to top of the carrier the exhaust gas is shown by arrows pointing upwards. Both the inlet gas ports 643 and exhaust ports 641 are shown in the gas manifold 640.

Furthermore, as shown in FIG. 6, the substrates may be positioned differently in the center channel—the substrates 686 are shown to be positioned in the channel a little further away from the mixing region than the substrates 684 in the two outer channels. This configuration effectively provides a slightly longer process gas preheat path for the center channel and may assist in maintaining temperature uniformity within the center channel. This substrate configuration may also be used in the substrate carrier of FIGS. 5A-5C.

The substrate carriers of FIGS. 5A-C & 6 may be used in combination with the CVD reactor configurations of FIGS. 2A-C & 4A-B.

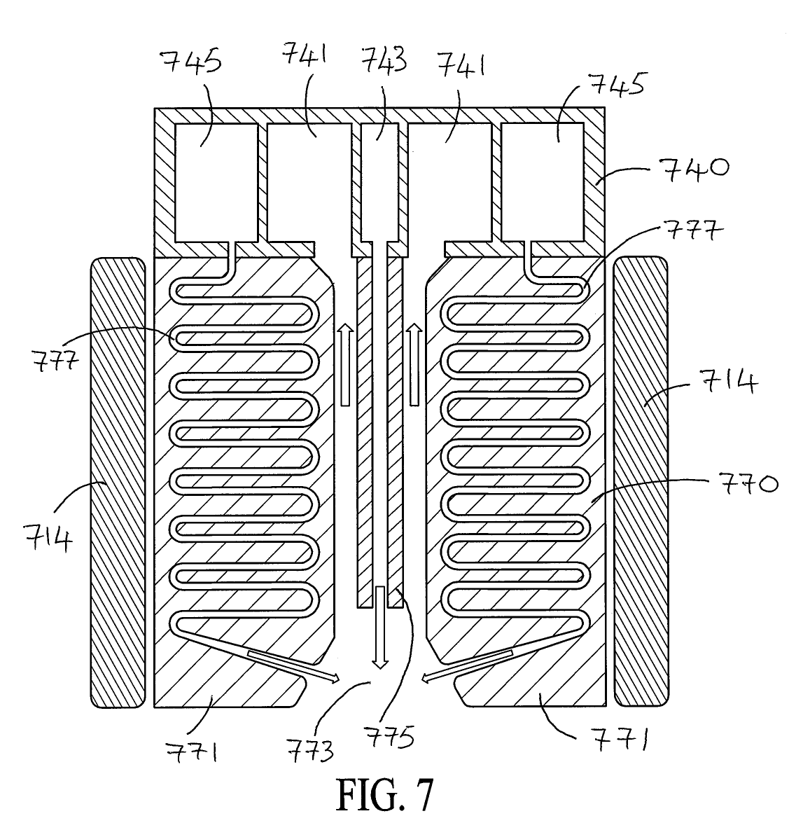

Furthermore, FIG. 7 shows a further embodiment of the manifold and preheat module of the substrate carrier that may be used with the substrate carriers described herein, and in the reactors described herein. The preheat module 770 is configured to separately heat process gases so as to reduce the amount of unwanted deposition that occurs on the walls of the preheat module. For example, when using TCS (trichlorosilane) and hydrogen gases for silicon deposition, the hydrogen may be heated more than the TCS within the preheat module and then combined in a gas mixing area 773 before entering the channels in the substrate holding part of the carrier (the latter is not shown in the figure, but could be configured as shown in the various figures of the present application). The manifold 740 comprises TCS gas port 743, hydrogen gas ports 745 and exhaust ports 741. The manifold is mated to the preheat module 770. The preheat module 770 comprises: outer portions 771 in which tortuous (for example, serpentine) channels 777 have been formed; inner walls 775 which form an isolated substantially straight channel through the preheat module for the TCS to flow, walls 775 also form exhaust channels. The tortuous channels 777 force the hydrogen gas into close contact with the heated channel walls over a long path, and the hydrogen flow dynamics through such a tortuous channel will result in disruption of the boundary layer on the channel wall. Heaters 714, which may be resistive or lamp heaters, as described herein above, provide heat to the preheat module 770. The heating can be controlled to ensure that the hydrogen gas exits the tortuous channel into the mixing area 773 at a temperature above Si deposition temperature, where it mixes with the cooler TCS before entering the channels on the walls of which the substrates are held. The low volume of TCS compared to hydrogen makes controlling the temperature of the mixed gases easier. This approach is expected to significantly reduce the amount of silicon deposition that occurs on the walls 775. As described for other embodiments substrate carriers are provide with two preheat modules to permit gas to be flowed in two directions over the substrates; the same approach can be used with preheat module 770, and the arrows in the figure show the two options—for the preheat section to be used to preheat process gases (downward pointing arrows) and for the preheat module to exhaust gases (upward pointing arrows).

Furthermore, another example of process chemicals that can be used in the preheat module of FIG. 7 are argon for preheating by passing through the tortuous channel and TCS mixed with one or more of methane and ethylene for passing through the substantially straight channel. This chemistry may be used for depositing SiC on the substrates. In general, the preheat module of FIG. 7 suits situations where one process gas is more thermally stable than another process gas, and the more thermally stable process gas is preheated to a higher temperature, allowing the less stable gas to be heated to a lower temperature through the preheat module, and yet deliver mixed process gases at the desired temperature to the surfaces of the substrates for depositing material. As discussed above this may result in less material being deposited on surfaces of the preheat module.

A method of operating a CVD reactor may comprise: flowing a first process gas from a first intake port of a gas manifold through a tortuous channel in an outer portion of a process gas preheat module into a mixing chamber; while flowing the first process gas, flowing a second process gas from a second intake port of the gas manifold through a substantially straight channel in an inner portion of the process gas preheat module into the mixing chamber; while flowing the first process gas and the second process gas, heating the gas preheat module with a heater external to the gas preheat module and adjacent to the outer portion; flowing a mixture of the first process gas and the second process gas from the mixing chamber through channels lined with a plurality of substrates and depositing material on the exposed surfaces of the plurality of substrates.

Although embodiments of the present disclosure have been particularly described with reference to certain embodiments thereof, it should be readily apparent to those of ordinary skill in the art that changes and modifications in the form and details may be made without departing from the spirit and scope of the disclosure.

What is claimed is:

1. A CVD reactor for depositing material on substrates, comprising:
a vacuum chamber;
at least two substrate carriers arranged in parallel in a row within said vacuum chamber, each of said at least two substrate carriers comprising mounting positions for a plurality of substrates, said mounting positions being on the walls of channels configured for flowing process gases, said channels being in parallel planes within all of said at least two substrate carriers;
a planar electrically resistive heater between every two adjacent substrate carriers in said row; and
planar heaters at both ends of said row.

2. The CVD reactor of claim 1, wherein said planar heaters are lamp heaters and said lamp heaters are mounted externally on said vacuum chamber.

3. The CVD reactor of claim 1, wherein said planar heaters are planar electrically resistive heaters and said planar heaters are mounted within said vacuum chamber.

4. The CVD reactor of claim 1, wherein said planar electrically resistive heater comprises a plurality of electrically resistive heating elements, wherein each of said plurality of electrically resistive heating elements defines a separately controllable heating zone.

5. The CVD reactor of claim 1, wherein said planar electrically resistive heater comprises a linear electrically resistive heating element with more resistive portions configured to provide extra heat to end caps of said substrate carriers.

6. The CVD reactor of claim 1, wherein said planar electrically resistive heater comprises silicon carbide coated graphite elements.

7. The CVD reactor of claim 1, wherein said material is epitaxial single crystal silicon and said substrates are single crystal silicon.

8. A substrate carrier for holding substrates in a CVD reactor, comprising:
mounting positions for a plurality of substrates, said mounting positions being on the walls of three channels configured for flowing process gases, said channels being in parallel planes within said substrate carrier; and
two gas preheat modules, a first of said two gas preheat modules being coupled to first ends of said three channels and a second of said two gas preheat modules being coupled to second ends of said three channels;
wherein mounting positions on the walls of the center of said three channels are positioned further from the proximate of said two gas preheat modules than the mounting positions on the walls of the outer two of the three channels.

9. A CVD reactor for depositing material on substrates, comprising:
a gas manifold;
a substrate carrier mated to said gas manifold, said substrate carrier comprising a process gas preheat module, said process gas preheat module comprising:
an outer portion with a tortuous channel therein;
an inner portion with a substantially straight channel therein; and
a gas mixing chamber, wherein said tortuous channel connects an intake port of a first process gas to said mixing chamber and said substantially straight channel connects an intake port of a second process gas to said mixing chamber; and
a heater external to said gas preheat module and adjacent to said outer portion.

10. The CVD reactor of claim 9, wherein said first process gas is more thermally stable than said second process gas.

11. The CVD reactor of claim 9, wherein said first process gas is hydrogen and said second process gas is TCS.

12. The CVD reactor of claim 9, wherein said first process gas is argon and said second process gas is a mixture of TCS with at least one of methane and ethylene.

13. A method of operating a CVD reactor, comprising:
flowing a first process gas from a first intake port of a gas manifold through a tortuous channel in an outer portion of a process gas preheat module into a mixing chamber;
while flowing said first process gas, flowing a second process gas from a second intake port of said gas manifold through a substantially straight channel in an inner portion of said process gas preheat module into said mixing chamber;
while flowing said first process gas and said second process gas, heating said gas preheat module with a heater external to said gas preheat module and adjacent to said outer portion;
flowing a mixture of said first process gas and said second process gas from said mixing chamber through channels lined with a plurality of substrates and depositing material on the exposed surfaces of said plurality of substrates.

14. The method of claim 13, wherein said first process gas is more thermally stable than said second process gas.

15. The method of claim 13, wherein said first process gas is hydrogen and said second process gas is TCS.

16. The method of claim 13, wherein said first process gas is argon and said second process gas is a mixture of TCS with at least one of methane and ethylene.
